(19) United States
(12) Patent Application Publication
(10) Pub. No.: US 2015/0364410 A1
(43) Pub. Date: Dec. 17, 2015

(54) CIRCUIT BOARD, MANUFACTURING METHOD THEREFOR, AND PILLAR-SHAPED TERMINAL FOR CIRCUIT BOARD

(71) Applicant: NGK SPARK PLUG CO., LTD., Nagoya-shi (JP)

(72) Inventors: Takuya HANDO, Inuyama-shi (JP); Atsuhiko SUGIMOTO, Kakamigahara-shi (JP)

(21) Appl. No.: 14/741,073

(22) Filed: Jun. 16, 2015

(30) Foreign Application Priority Data
Jun. 17, 2014 (JP) 2014-124051
Apr. 13, 2015 (JP) 2015-081403

(51) Int. Cl. H01L 23/498; H01R 43/20; H01L 21/768

(52) U.S. Cl. CPC H01L 23/49838; H01L 23/49827; H01L 23/49866; H01L 21/76885; H01R 43/205

(57) ABSTRACT

A circuit board according to the present invention includes a first substrate that is or is to be connected to a second substrate. Electrodes are arranged on a principal surface of the first substrate, and pillar-shaped terminals are bonded to the respective electrodes with solder portions provided therebetween. Each pillar-shaped terminal includes a pillar-shaped terminal body and a solder blocking layer that covers a central region of an outer peripheral surface of the pillar-shaped terminal body in a height direction, and the pillar-shaped terminal has a shape that is vertically symmetrical about the solder blocking layer. The area of a region of the outer peripheral surface of the pillar-shaped terminal body that is not covered with the solder blocking layer is larger than the area of the region of the outer peripheral surface that is covered with the solder blocking layer.

### CROSS REFERENCE TO RELATED APPLICATIONS

The present application claims priority from Japanese Patent Application No. 2014-124051, which was filed on Jun. 17, 2014, and Japanese Patent Application No. 2015-081403, which was filed on Apr. 13, 2015, the disclosures of which are herein incorporated by reference in their entirety.

### BACKGROUND OF THE INVENTION

1. Field of the Invention

The present invention relates to a circuit board including a substrate that is or is to be connected to another substrate, a method for manufacturing the circuit board, and a pillar-shaped terminal used to connect the substrates.

2. Description of the Related Art

In recent years, electrical and electronic apparatuses have continued to decrease in size, and accordingly there has been a need to reduce the size and increase the density of circuit boards or the like included in these apparatuses. To meet such a need, a circuit board having a package on package (POP) structure, in which a plurality of substrates (so-called packages) are stacked on top of each other, has been proposed (see, for example, Japanese Unexamined Patent Application Publication No. 2012-9782 (FIG. 1) and Japanese Unexamined Patent Application Publication No. 2008-159956 (FIG. 1)). The substrates may be connected to each other by, for example, the following method. That is, a plurality of electrodes are provided on a principal surface of a lower substrate, and terminals having a length of 100 μm or less (so-called micro-pins) are bonded to the respective electrodes with solder portions provided therebetween. Then, distal ends of the terminals are connected to an upper substrate. In general, a semiconductor integrated circuit element (IC chip), which is used as a microprocessor or the like of a computer, is mounted on the principal surface. Therefore, a gap greater than or equal to the height of the IC chip needs to be provided between the upper and lower substrates.

The above-described micro-pins need to be bonded by using a dedicated positioning jig. More specifically, first, a lower substrate 153 is prepared (see FIG. 16). A plurality of electrodes 152 are formed on a principal surface 151 of the lower substrate 153, and solder paste is applied to each electrode 152. A plurality of micro-pins 154 are inserted into pin-receiving holes 156 of a positioning jig 155, and are placed below the lower substrate 153. Then, a reflow process is performed to heat and melt the solder paste so that each micro-pin 154 is bonded to the corresponding electrode 152 and stands upright. Thus, when the distal ends of the micro-pins 154 are connected to an upper substrate, a gap greater than or equal to the height of the IC chip can be reliably provided between the upper substrate and the lower substrate 153.

In recent years, with the reduction in size of the circuit board, the pitch between the adjacent micro-pins 154 has been reduced, and the pitch between the adjacent pin-receiving holes 156 has been reduced accordingly. However, when the pitch is reduced to, for example, 100 μm or less, it becomes difficult to manufacture the positioning jig 155. Even when a positioning jig in which the pitch is 100 μm or less can be manufactured, it is difficult to perform a reflow process while the micro-pins are inserted in the pin-receiving holes. Therefore, it is difficult to arrange the micro-pins to be upright.

### BRIEF SUMMARY OF THE INVENTION

The present invention has been made in light of the above-described problems, and a first object of the present invention is to provide a circuit board in which pillar-shaped terminals can be easily arranged upright so that a first substrate can be easily connected to a second substrate with the pillar-shaped terminals provided therebetween, and to provide a method for manufacturing the circuit board. A second object of the present invention is to provide a pillar-shaped terminal suitable for the circuit board.

According to one aspect of the invention, a circuit board includes a first substrate that is or is to be connected to a second substrate (i.e., the first substrate is for connecting to a second substrate), wherein a plurality of electrodes are arranged on a principal surface of the first substrate, and a plurality of pillar-shaped terminals are bonded to the respective electrodes with solder portions provided therebetween, the pillar-shaped terminals being used to connect the first substrate to the second substrate. Each pillar-shaped terminal includes a pillar-shaped terminal body made of a conductive material and a solder blocking layer that is made of a material having a solder wettability lower than a solder wettability of the pillar-shaped terminal body and that covers a central region of an outer peripheral surface of the pillar-shaped terminal body in a height direction.

In one embodiment, the pillar-shaped terminal has a shape that is vertically symmetrical about the solder blocking layer. An area of a region of the outer peripheral surface of the pillar-shaped terminal body that is not covered with the solder blocking layer is larger than an area of the region of the outer peripheral surface that is covered with the solder blocking layer.

According to the above-described circuit boards, the central region of each pillar-shaped terminal (pillar-shaped terminal body) in the height direction is covered with the solder blocking layer. Therefore, in the process of bonding the pillar-shaped terminal to the corresponding electrode, when at least a portion of the pillar-shaped terminal is immersed in the corresponding solder portion that is heated and melted, the pillar-shaped terminal is influenced by the surface tension or the like of the solder in the liquid phase and changes its orientation so as to balance its weight. As a result, the pillar-shaped terminal stands upright by itself. Since the solder blocking layer is made of the material having a solder wettability lower than that of the pillar-shaped terminal body, the solder blocking layer repels the solder portion in the liquid phase so that the solder portion accumulates in, for example, a region near the electrode. This further makes it easier for the pillar-shaped terminal to stand upright. Accordingly, even when the pitch between the adjacent terminals is reduced with a reduction in the size of the circuit board, since the pillar-shaped terminals that easily stand upright are used as the terminals, a circuit board in which the first substrate can be easily connected to the second substrate with the pillar-shaped terminals provided therebetween can be provided.

The solder wettabilities of the pillar-shaped terminal body and the solder blocking layer are measured by the following method. That is, first, the compositions of the surface of the pillar-shaped terminal body and the surface of the solder blocking layer are determined by a metal or organic analysis. The metal or organic analysis may be performed by, for example, EPMA, XPS, AES, FE-AES, FTIR, SIMS, or TOF-SIMS. Next, scale-up evaluation samples of the pillar-shaped terminal body and the solder blocking layer having the compositions determined by the above-described analysis are produced, and the solder wettabilities of the pillar-shaped terminal body and the solder blocking layer are evaluated by a measurement method according to JIS 23197.

There is no particular limitation regarding the materials of the first and second substrates. However, resin substrates, for example, are preferred. Preferred examples of resin substrates include substrates made of an epoxy resin, a polyimide resin, a bismaleimide-triazine resin, and a polyphenylene ether resin. Alternatively, substrates made of composite materials of these resins and glass fibers (glass woven fabric or glass nonwoven fabric) may be used. Alternatively, various types of ceramics may instead be used as the materials. There is also no particular limitation regarding the structures of the first and second substrates. For example, multilayer build-up substrates including build-up layers on one side or both sides of a core substrate, or coreless substrates that do not include a core substrate may be used.

The electrodes are arranged on the principal surface of the first substrate. The electrodes may be arranged either only on the principal surface of the first substrate or on both the principal surface and back surface of the first substrate. The electrodes may be made of a conductive metal material or the like. The metal material of the electrodes may be, for example, copper, silver, iron, cobalt, or nickel. In particular, the electrodes are preferably made of copper, which is highly conductive and inexpensive. The electrodes are preferably formed by plating. In such a case, electrodes having a uniform size can be formed with high accuracy. If, for example, the electrodes are formed by printing by using a metal paste, it is difficult to form electrodes having a uniform size with high accuracy. Therefore, there is a risk that electrodes having different heights will be formed.

The pillar-shaped terminals used to connect the first substrate to the second substrate are bonded to the respective electrodes with the solder portions provided therebetween. Each pillar-shaped terminal includes the pillar-shaped terminal body made of the conductive material and the solder blocking layer that is made of the material having a solder wettability lower than that of the pillar-shaped terminal body and that covers the central region of the outer peripheral surface of the pillar-shaped terminal body in the height direction. There is no particular limitation regarding the shape of the pillar-shaped terminal body, and the pillar-shaped terminal body may have any shape. For example, the pillar-shaped terminal body may have an end surface in the height direction (top or bottom end surface) that is flat. In such a case, the end surface of the pillar-shaped terminal body has a shape that follows the surface of the corresponding electrode. Therefore, when each pillar-shaped terminal is bonded to the corresponding electrode with the solder portion provided therebetween, the gap between the end surface of the pillar-shaped terminal body and the surface of the electrode is small. As a result, movement of the pillar-shaped terminal can be suppressed and the pillar-shaped terminal stands upright reliably.

The conductive material of the pillar-shaped terminal body may be, for example, copper, silver, iron, cobalt, or nickel. In particular, the pillar-shaped terminal body is preferably made of copper. In such a case, compared to the case in which the pillar-shaped terminal body is made of another material, the resistance of the pillar-shaped terminal body can be reduced and the conductivity of the pillar-shaped terminal body can be increased. Moreover, since the pillar-shaped terminal body is made of copper, which has a relatively high solder wettability, the bonding strength between the pillar-shaped terminal body and the solder portion can be increased, and the bonding strength between the pillar-shaped terminal and the electrode can be increased accordingly. In other words, by using a pillar-shaped terminal suitable for connection with the electrode, the reliability of the circuit board can be increased.

There is also no particular limitation regarding the material of the solder blocking layer except that the material is to have a solder wettability lower than that of the pillar-shaped terminal body. For example, a resin material, a metal material, or a ceramic material may be used. Examples of resin materials that may be used as the material of the solder blocking layer include an epoxy resin, a phenol resin, a urethane resin, a silicone resin, a polyimide resin, a bismaleimide-triazine resin, and a polyphenylene ether resin. Examples of metal materials that may be used as the material of the solder blocking layer include cobalt, nickel, tungsten, molybdenum, and manganese. Examples of ceramic materials that may be used as the material of the solder blocking layer include a high-temperature-fired ceramic such as alumina, aluminum nitride, boron nitride, silicon carbide, or silicon nitride, a low-temperature-fired ceramic such as a glass ceramic, a ceramic such as barium titanate, lead titanate, and strontium titanate.

The solder blocking layer may project from the outer peripheral surface of the pillar-shaped terminal body. In such a case, when each pillar-shaped terminal is bonded to the corresponding electrode, the solder blocking layer repels the solder portion in the liquid phase so that and the solder portion accumulates in, for example, a region near the electrode. As a result, the end surface of the pillar-shaped terminal body that is closer than the solder blocking layer to the electrode is supported by the solder portion, so that the pillar-shaped terminal stands upright reliably. Accordingly, a circuit board can be reliably provided such that a sufficient gap is provided between the first and second substrates when the first substrate is connected to the second substrate with the pillar-shaped terminals therebetween.

The solder blocking layer may extend along the entire perimeter of the outer peripheral surface of the pillar-shaped terminal body in the central region of the pillar-shaped terminal body in the height direction. In such a case, when each pillar-shaped terminal is bonded to the corresponding electrode and the solder blocking layer repels the solder portion in the liquid phase so that the solder portion moves toward, for example, the electrode, the top end of the solder portion is prevented from flowing upward beyond the solder blocking layer. As a result, the solder blocking layer is more reliably supported by the solder portion. In addition, since the solder blocking layer is provided on the central portion of the pillar-shaped terminal body in the height direction, the pillar-shaped terminal has a good weight balance. Therefore, the pillar-shaped terminal stands upright more reliably. Accordingly, a circuit board can be more reliably provided such that a sufficient gap is provided between the first and second substrates when the first substrate is connected to the second substrate with the pillar-shaped terminals therebetween.

There is no particular limitation regarding the solder material of the solder portions. For example, a Pb—Sn-based solder, such as 90Pb-10Sn, 95Pb-5Sn, or 40Pb-60Sn, a Sn—Sb-based solder, a Sn—Ag-based solder, a Sn—Ag—Cu-based solder, an Au—Ge-based solder, an Au—Sn-based solder, or an Au—Si-based solder may be used. In particular, the solder portions are preferably made of a lead-free solder. In such a case, environmental stress caused by the circuit board can be reduced.

According to another aspect of the invention, a method for manufacturing a circuit board as described above includes a substrate preparation step of preparing the first substrate having the electrodes arranged on the principal surface thereof; a solder-paste supplying step of supplying a solder paste to the electrodes; a pillar-shaped-terminal arranging step of arranging the pillar-shaped terminals on the respective electrodes to which the solder paste has been supplied; and a reflow step of heating and melting the solder paste so that at least portions of the pillar-shaped terminals are immersed in the solder paste and the pillar-shaped terminals stand upright.

According to the above-described method, the central region of each of the pillar-shaped terminals, which are arranged on the respective electrodes in the pillar-shaped-terminal arranging step, in the height direction is covered with the solder blocking layer. Therefore, in the reflow step, when at least a portion of each pillar-shaped terminal is immersed in the solder paste that is heated and melted, the pillar-shaped terminal is influenced by the surface tension or the like of the solder in the liquid phase and changes its orientation so as to balance its weight. As a result, the pillar-shaped terminal stands upright by itself. Since the solder blocking layer is made of the material having a solder wettability lower than that of the pillar-shaped terminal body, the solder blocking layer repels the solder paste in the liquid phase so that the solder paste accumulates in, for example, a region near the electrode. This further makes it easier for the pillar-shaped terminal to stand upright. Accordingly, even when the pitch between the adjacent terminals is reduced with a reduction in the size of the circuit board, the pillar-shaped terminals stand upright by themselves when the reflow step is performed. Therefore, a circuit board in which the first substrate can be easily connected to the second substrate with the pillar-shaped terminals provided therebetween can be provided.

The method for manufacturing the circuit board will now be described.

First, the substrate preparation step is performed to prepare the first substrate having the electrodes arranged on the principal surface thereof. Next, in the solder-paste supplying step, the solder paste is supplied to the electrodes.

The principal surface may be covered with a solder resist layer, and the electrodes may be exposed at openings that extend through the solder resist layer in a thickness direction. In such a case, in the solder-paste supplying step, the solder paste may be supplied to the openings. Thus, the solder paste can be reliably supplied to the electrodes, and the circuit board can be easily manufactured.

The solder blocking layer included in each pillar-shaped terminal may be made of the same resin material as the material of the solder resist layer, or a resin material different from the material of the solder resist layer. Preferably, the solder blocking layer is made of the same resin material as the material of the solder resist layer. In such a case, it is not necessary to prepare different resin materials for the solder blocking layer and the solder resist layer, and therefore the manufacturing cost of the circuit board can be reduced. The material of the solder resist layer may be selected as appropriate in consideration of, for example, insulation performance, heat resistance, and moisture resistance. A resin material suitable for the solder resist layer includes an epoxy resin, a phenol resin, a urethane resin, a silicone resin, and a polyimide resin.

Next, in the pillar-shaped-terminal arranging step, the pillar-shaped terminals are arranged on the respective electrodes to which the solder paste has been supplied. Then, in the reflow step, the solder paste is heated and melted so that at least portions of the pillar-shaped terminals are immersed in the solder paste and the pillar-shaped terminals stand upright. The circuit board is manufactured by the above-described processes.

According to yet another aspect of the invention, a pillar-shaped terminal for a circuit board includes a first substrate that is or is to be connected to a second substrate (i.e., the first substrate is for connecting to a second substrate), the pillar-shaped terminal including a pillar-shaped terminal body made of a conductive material, and a solder blocking layer that is made of a material having a solder wettability lower than a solder wettability of the pillar-shaped terminal body and that covers a central region of an outer peripheral surface of the pillar-shaped terminal body in a height direction.

In an embodiment, the pillar-shaped terminal has a shape that is vertically symmetrical about the solder blocking layer. An area of a region of the outer peripheral surface of the pillar-shaped terminal body that is not covered with the solder blocking layer is larger than an area of the region of the outer peripheral surface that is covered with the solder blocking layer.

According to the above-described pillar-shaped terminals for circuit boards, the central region of the pillar-shaped terminal body in the height direction is covered with the solder blocking layer. Therefore, in the process of bonding each pillar-shaped terminal to the corresponding electrode on the first substrate, when at least a portion of the pillar-shaped terminal is immersed in the solder paste that is heated and melted, the pillar-shaped terminal is influenced by the surface tension or the like of the solder in the liquid phase and changes its orientation so as to balance its weight. As a result, the pillar-shaped terminal stands upright by itself. Since the solder blocking layer is made of the material having a solder wettability lower than that of the pillar-shaped terminal body, the solder blocking layer repels the solder paste in the liquid phase so that the solder paste accumulates in, for example, a region near the electrode. This further makes it easier for the pillar-shaped terminal to stand upright. Accordingly, since the pillar-shaped terminal that easily stands upright is used, a circuit board in which the first substrate can be easily connected to the second substrate with the pillar-shaped terminal provided therebetween can be provided.

### BRIEF DESCRIPTION OF THE DRAWINGS

Illustrative aspects of the invention will be described in detail with reference to the following figures wherein:

FIG. 1 is a schematic sectional view illustrating the structure of a circuit board according to an embodiment;

FIG. 2 is a sectional view illustrating a main part of a first substrate;

FIG. 3 is a top view of a pillar-shaped terminal;

FIG. 4 illustrates a solder-blocking-layer forming step;

FIG. 5 also illustrates the solder-blocking-layer forming step;

FIG. 6 illustrates a step of forming a base material including a support substrate and an underlying resin insulating layer;

FIG. 7 illustrates a step of forming a conductor layer on the resin insulating layer;

FIG. 8 illustrates a step of forming a multilayer unit;

FIG. 9 illustrates a step of separating the multilayer unit from the support substrate;

FIG. 10 illustrates a step of forming electrodes on a back surface of the resin insulating layer;

FIG. 11 illustrates a solder-paste supplying step;

FIG. 12 illustrates a pillar-shaped-terminal arranging step;

FIG. 13 is a sectional view of a pillar-shaped terminal according to another embodiment;

FIG. 14 is a top view of a pillar-shaped terminal according to another embodiment;

FIG. 15 is a solder-blocking-layer forming step according to another embodiment; and

FIG. 16 illustrates a manufacturing method of a circuit board according to the related art.

### DETAILED DESCRIPTION OF EXEMPLARY EMBODIMENTS OF THE INVENTION

An embodiment of the present invention will be described in detail with reference to the accompanying drawings.

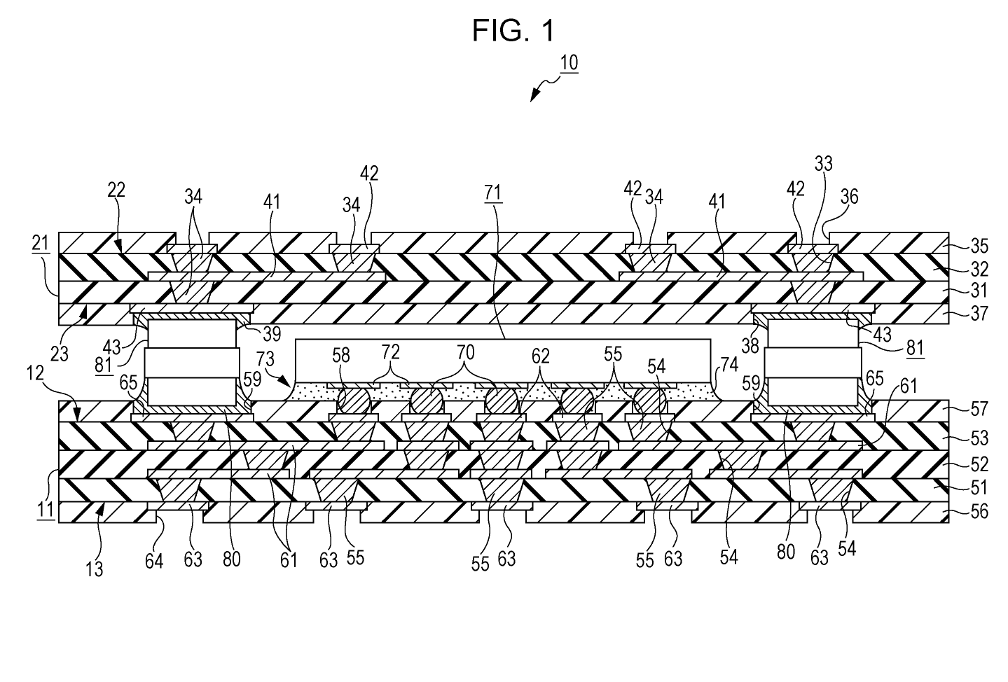

FIG. 1 is a schematic sectional view of a circuit board 10 according to the present embodiment. The circuit board 10 includes a first substrate 11 and a second substrate 21.

The second substrate 21 is structured such that two resin insulating layers 31 and 32, which are made of an epoxy resin, and a conductor layer 41, which is made of copper, are alternately stacked. Each of the resin insulating layers 31 and 32 is provided with via holes 33 and via conductors 34. The via holes 33 have a truncated conical shape, and are formed in the resin insulating layers 31 and 32 by a hole-forming process performed by a YAG laser or a carbon dioxide laser. The via conductors 34 are shaped such that the diameters thereof increase toward a certain direction (upward in FIG. 1).

An array of principal-surface-side electrodes 42 (15 μm thick), which are electrically connected to the conductor layer 41 by the via conductors 34, is provided on a principal surface 22 of the second substrate 21 (front surface of the second resin insulating layer 32). The front surface of the resin insulating layer 32 is substantially entirely covered with a solder resist layer 35 made of an epoxy resin and having a thickness of about 30 μm. The solder resist layer 35 has openings 36 at predetermined positions. The openings 36 extend through the solder resist layer 35 in the thickness direction so that the principal-surface-side electrodes 42 are exposed at the openings 36.

Back-surface-side electrodes 43 (15 μm thick), which are electrically connected to the conductor layer 41 by the via conductors 34, are provided on a back surface 23 of the second substrate 21 (bottom surface of the first resin insulating layer 31) at multiple positions. The bottom surface of the resin insulating layer 31 is substantially entirely covered with a solder resist layer 37 made of an epoxy resin and having a thickness of about 30 μm. The solder resist layer 37 has openings 38 at predetermined positions. The openings 38 extend through the solder resist layer 37 in the thickness direction so that the back-surface-side electrodes 43 are exposed at the openings 38. Solder portions 39 are provided on the back-surface-side electrodes 43 that are exposed at the openings 38.

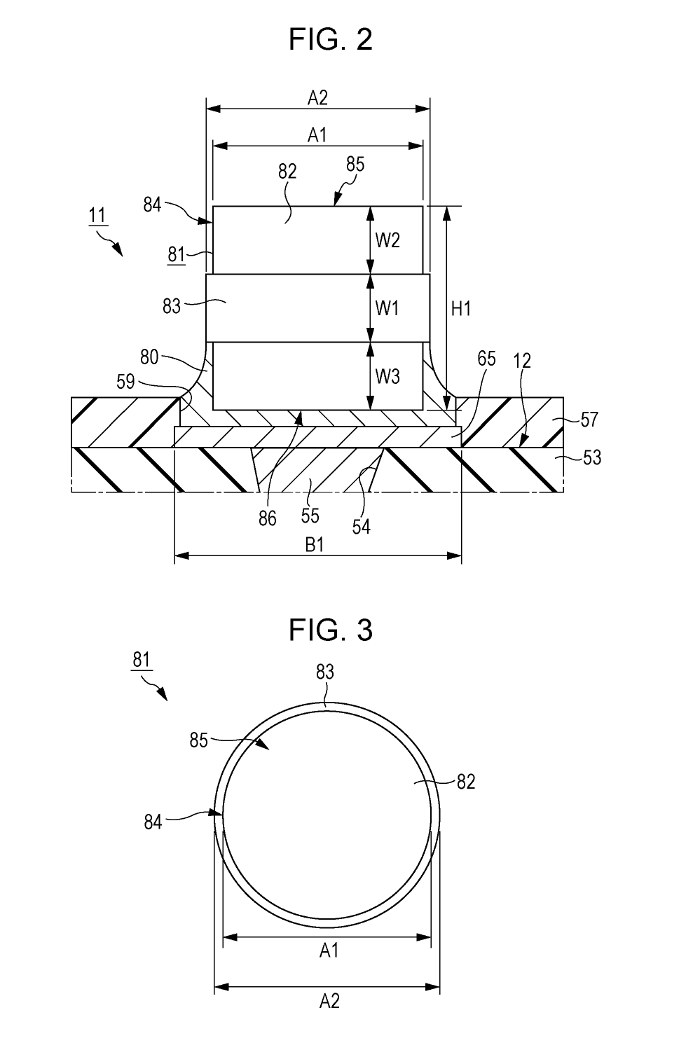

As illustrated in FIGS. 1 and 2, the first substrate 11 is connected to the above-described second substrate 21, and has substantially the same structure as that of the second substrate 21. More specifically, the first substrate 11 is structured such that three resin insulating layers 51, 52, and 53, which are made of an epoxy resin, and conductor layers 61, which are made of copper, are alternately stacked. Each of the resin insulating layers 51 to 53 is provided with via holes 54 and via conductors 55. The via holes 54 have a truncated conical shape, and are formed in the resin insulating layers 51 to 53 by a hole-forming process performed by a YAG laser or a carbon dioxide laser. The via conductors 55 are shaped such that the diameters thereof increase toward a certain direction (upward in FIG. 1), and electrically connect the conductor layers 61 to each other.

As illustrated in FIG. 1, back-surface-side electrodes 63 (15 μm thick), which are electrically connected to the conductor layers 61 by the via conductors 55, are provided on a back surface 13 of the first substrate 11 (bottom surface of the first resin insulating layer 51) at multiple positions. The bottom surface of the resin insulating layer 51 is substantially entirely covered with a solder resist layer 56 made of an epoxy resin and having a thickness of about 30 μm. The solder resist layer 56 has openings 64 at predetermined positions. The openings 64 extend through the solder resist layer 56 in the thickness direction so that the back-surface-side electrodes 63 are exposed at the openings 64. A plurality of solder bumps (not shown), which can be electrically connected to a mother board (not shown), are provided on surfaces of the back-surface-side electrodes 63. The first substrate 11 is mounted on the mother board by using the solder bumps.

As illustrated in FIG. 1, an array of principal-surface-side electrodes 62, which are electrically connected to the conductor layers 61 by the via conductors 55, is provided on a principal surface 12 of the first substrate 11 (front surface of the third resin insulating layer 53). The front surface of the resin insulating layer 53 (principal surface 12) is substantially entirely covered with a solder resist layer 57 made of an epoxy resin and having a thickness of about 30 μm. The solder resist layer 57 has openings 58 at predetermined positions. The openings 58 extend through the solder resist layer 57 in the thickness direction so that the principal-surface-side electrodes 62 are exposed at the openings 58. The principal-surface-side electrodes 62 are connected to connection terminals 72, which are arranged on the bottom surface of a rectangular plate-shaped IC chip 71, with solder bumps 70 provided therebetween. The region in which the principal-surface-side electrodes 62 are provided corresponds to an IC-chip receiving region 73 in which the IC chip 71 can be mounted.

As illustrated in FIG. 1, the gap between the solder resist layer 57 and the IC chip 71 is filled with an underfill 74. As a result, the first substrate 11 and the IC chip 71 are fixed to each other while the gap therebetween is sealed. In the present embodiment, the underfill 74 is made of an epoxy resin having a coefficient of thermal expansion of about 20 to 60 ppm/° C. (more specifically, 34 ppm/° C.).

As illustrated in FIGS. 1 and 2, principal-surface-side electrodes 65, which are electrically connected to the conductor layers 61 by the via conductors 55, are provided on the principal surface 12 of the first substrate 11 at multiple positions. Referring to FIG. 2, each principal-surface-side electrode 65 has a circular shape in plan view, and has an outer diameter B1 of 100 μm and a thickness of 15 μm. The outer diameter B1 is set so as to be greater than the outer diameter of each via conductor 55 at the top end (30 μm). The solder resist layer 57 has openings 59 at predetermined positions. The openings 59 extend through the solder resist layer 57 in the thickness direction so that the principal-surface-side electrodes 65 are exposed at the openings 59. In the present embodiment, the inner diameter of the openings 59 is set to 95 μm.

A plurality of pillar-shaped terminals 81, which are used to electrically connect the first substrate 11 to the second substrate 21, are bonded to the respective principal-surface-side electrodes 65 with solder portions 80 provided therebetween. More specifically, the bottom ends of the pillar-shaped terminals 81 are bonded to the respective principal-surface-side electrodes 65 with the solder portions 80 provided therebetween, and the top ends of the pillar-shaped terminals 81 are bonded to the back-surface-side electrodes 43 of the second substrate 21 with the solder portions 39 provided therebetween. The pillar-shaped terminals 81 are soldered by using a solder having a melting point higher than that of the solder bumps 70 used to mount the IC chip 71. More specifically, a Sn—Ag—Cu-based solder is used as the solder material of the solder portions 39 and 80 according to the present embodiment.

Referring to FIGS. 1 to 3, each pillar-shaped terminal 81 includes a pillar-shaped terminal body 82 that has a columnar shape and a solder blocking layer 83 that has a cylindrical shape. The pillar-shaped terminal body 82 is made of copper, which is a conductive material, and a surface thereof is coated with a nickel layer and a gold layer. The nickel layer is a plating layer formed on the surface of the pillar-shaped terminal body 82 by electroless nickel plating. The gold layer is a plating layer formed by electroless gold plating so as to cover the nickel layer.

Referring to FIGS. 2 and 3, the outer diameter A1 of the pillar-shaped terminal body 82 is set to 45 μm, and the height H1 of the pillar-shaped terminal body 82 is set to 90 μm. In other words, in the present embodiment, a micro-pin having a height H1 (length) of 100 μm or less is used as each pillar-shaped terminal 81. The ratio of the height H1 of the pillar-shaped terminal body 82 to the outer diameter A1 of the pillar-shaped terminal body 82 is set to 2:1. The height H1 of the pillar-shaped terminal body 82 is smaller than the inner diameter of each opening 59 in the solder resist layer 57 (95 μm).

The solder blocking layer 83 is made of an epoxy resin, which is a material having a solder wettability lower than that of the pillar-shaped terminal body 82. More specifically, the solder blocking layer 83 is made of the same resin material as the material of the solder resist layers 35, 37, 56, and 57. The solder blocking layer 83 covers a central region of an outer peripheral surface 84 of the pillar-shaped terminal body 82 in the height direction. The solder blocking layer 83 extends over the entire perimeter of the outer peripheral surface 84 of the pillar-shaped terminal body 82 in the central region of the pillar-shaped terminal body 82 in the height direction. In the present embodiment, the width W1 of the solder blocking layer 83 is set to 30 μm. In addition, in the present embodiment, the width W2 of a region of the outer peripheral surface 84 that projects upward from the solder blocking layer 83 is set to 30 μm, and the width W3 of a region of the outer peripheral surface 84 that projects downward from the solder blocking layer 83 is also set to 30 μm. Thus, the pillar-shaped terminal 81 has a shape that is vertically symmetrical about the solder blocking layer 83. The total area of the regions of the outer peripheral surface 84 that are not covered by the solder blocking layer 83 is greater than the area of the region of the outer peripheral surface 84 that is covered by the solder blocking layer 83.

As illustrated in FIGS. 2 and 3, the solder blocking layer 83 projects from the outer peripheral surface 84 of the pillar-shaped terminal body 82. The amount by which the solder blocking layer 83 projects from the outer peripheral surface 84 is set to 5 μm in the present embodiment. The outer diameter A2 of the solder blocking layer 83 is set so as to be greater than the outer diameter A1 of the pillar-shaped terminal body 82 (45 μm), and is set to 55 μm in the present embodiment. The outer diameter A2 is the maximum diameter of the pillar-shaped terminal 81. The outer diameter A2 of the solder blocking layer 83 is smaller than the above-described outer diameter B1 (100 μm), which is the maximum diameter of the principal-surface-side electrode 65. In addition, the inner diameter of the opening 59 in the solder resist layer 57 (about 95 μm) is greater than the maximum diameter of the pillar-shaped terminal 81 (55 μm).

As illustrated in FIGS. 1 and 2, each pillar-shaped terminal 81 is bonded to the corresponding principal-surface-side electrode 65 with the corresponding solder portion 80 provided therebetween, in such a manner that the bottom end thereof is inserted into the solder portion 80. The pillar-shaped terminal body 82 has a bottom end surface 86 that is flat and extends parallel to the surface of the principal-surface-side electrode 65 with a space provided between the bottom end surface 86 and the principal-surface-side electrode 65. The distance between the bottom end surface 86 and the surface of the principal-surface-side electrode 65 is set to 20 μm in the present embodiment. The solder portion 80 covers the entire region of the surface of the principal-surface-side electrode 65 that is exposed at the opening 59. The solder portion 80 also covers the entire bottom end surface 86 of the pillar-shaped terminal body 82, the entire region of the outer peripheral surface 84 that projects downward from the solder blocking layer 83, and the bottom end surface of the solder blocking layer 83 (surface facing the principal-surface-side electrode 65). In other words, the solder portion 80 projects upward from the opening 59, and the upper end thereof is in contact with the solder blocking layer 83.

In addition, as illustrated in FIG. 1, each pillar-shaped terminal 81 is bonded to the corresponding back-surface-side electrode 43 with the corresponding solder portion 39 provided therebetween, in such a manner that the top end thereof is inserted into the solder portion 39. The pillar-shaped terminal body 82 has a top end surface 85 that is flat and extends parallel to the surface of the back-surface-side electrode 43 with a space provided between the top end surface 85 and the surface (bottom surface) of the back-surface-side electrode 43. The distance between the top end surface 85 and the surface of the back-surface-side electrode 43 is set to 20 μm in the present embodiment. The solder portion 39 covers the entire region of the surface of the back-surface-side electrode 43 that is exposed at the opening 38. The solder portion 39 also covers the entire top end surface 85 of the pillar-shaped terminal body 82, and part of the region of outer peripheral surface 84 that projects upward from the solder blocking layer 83.

Next, a method for manufacturing the circuit board 10 will be described.

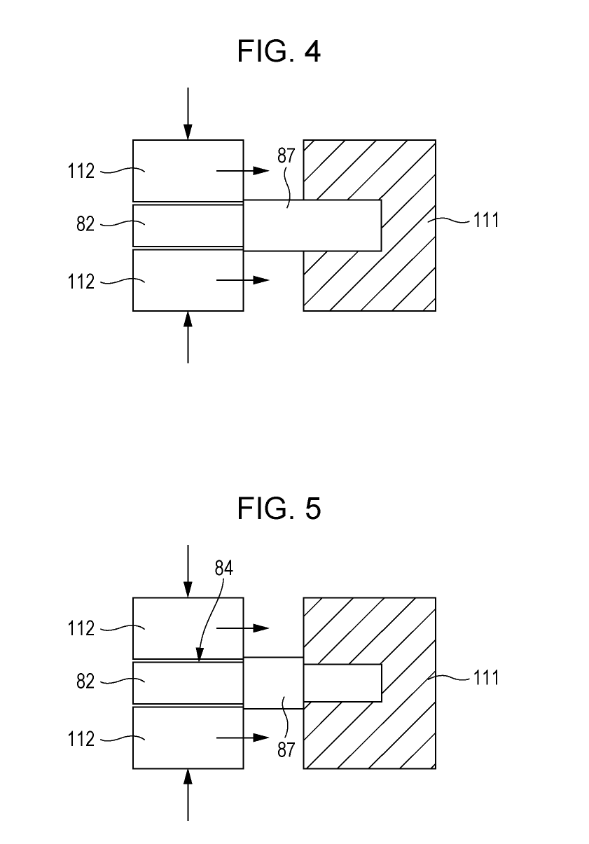

First, each pillar-shaped terminal 81 is produced. More specifically, in a pillar-shaped-terminal-body preparation step, the pillar-shaped terminal body 82 is produced. Next, in a material applying step, the entire outer peripheral surface 84 of the pillar-shaped terminal body 82 is coated with a material (see FIG. 4) having a solder wettability lower than that of the pillar-shaped terminal body 82. In the present embodiment, the material 87 is an epoxy resin.

Next, in a solder-blocking-layer forming step, portions of the material 87 that cover the end portions of the pillar-shaped terminal body 82 are removed. More specifically, first, a first end portion (right end portion in FIG. 4) of the pillar-shaped terminal body 82 is attached to a chuck 111. In this state, a portion of the material 87 (see FIG. 4) that covers a second end portion (left end portion in FIG. 4) of the pillar-shaped terminal body 82 is removed by a cutting process performed by a cutting tool 112 attached to a lathe. Next, the second end portion (right end portion in FIG. 5) of the pillar-shaped terminal body 82 is attached to the chuck 111. In this state, a portion of the material 87 that covers the first end portion (left end portion in FIG. 5) of the pillar-shaped terminal body 82 is removed by a cutting process performed by the cutting tool 112. A portion of the material 87 that remains after the cutting process serves as the solder blocking layer 83 that covers a central region of the outer peripheral surface 84 of the pillar-shaped terminal body 82 in the height direction. Then, unnecessary portions at both ends of the pillar-shaped terminal body 82 are cut. Thus, the pillar-shaped terminal 81 is completed.

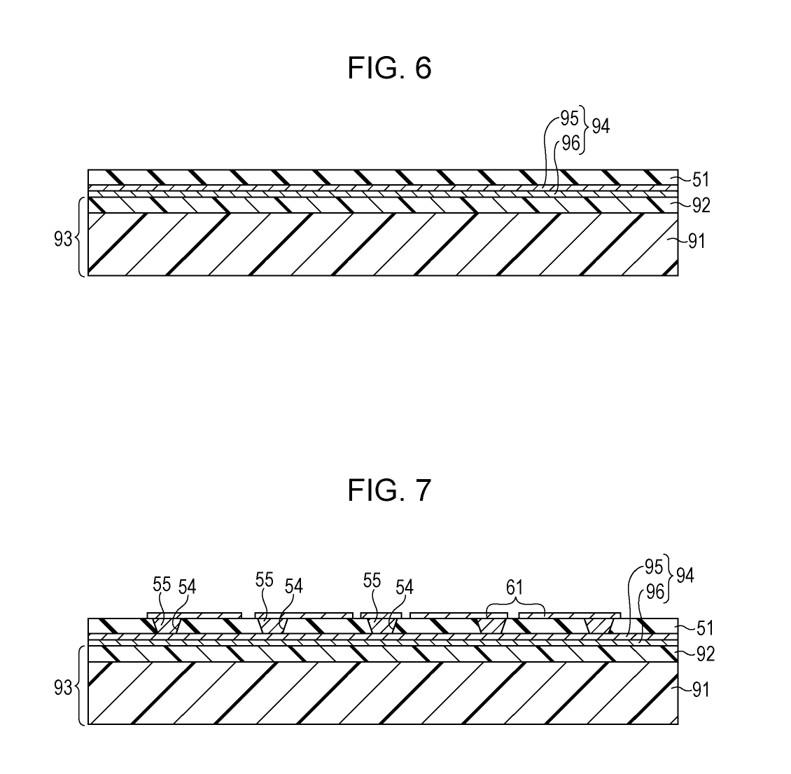

A substrate preparation step is performed to produce an intermediate product of the first substrate 11. The intermediate product of the first substrate 11 is structured such that a plurality of product units, each of which serves as the first substrate 11, are arranged along a plane. The intermediate product of the first substrate 11 is produced by the following method. That is, first, a support substrate 91 having a sufficient strength, such as a glass epoxy substrate, is prepared (see FIG. 6). Next, an underlying resin insulating layer 92 is formed by bonding a sheet-shaped insulating resin base material, which is made of an epoxy resin, to the support substrate 91 while the insulating resin base material is in a semi-cured state. Thus, a base material 93 including the support substrate 91 and the underlying resin insulating layer 92 is obtained (see FIG. 6). Then, a multilayer metal sheet 94 is provided on one surface of the base material 93 (more specifically, on the top surface of the underlying resin insulating layer 92) (see FIG. 6). Since the multilayer metal sheet 94 is provided on the underlying resin insulating layer 92 that is in a semi-cured state, the adhesion force applied therebetween is strong enough to prevent the multilayer metal sheet 94 from being separated from the underlying resin insulating layer 92 in the subsequent manufacturing steps. The multilayer metal sheet 94 includes two copper films 95 and 96 that are bonded together in such a manner that they can be separated from each other. More specifically, the multilayer metal sheet 94 is formed by stacking the copper films 95 and 96 with a metal plating (for example, chromium plating) layer interposed therebetween.

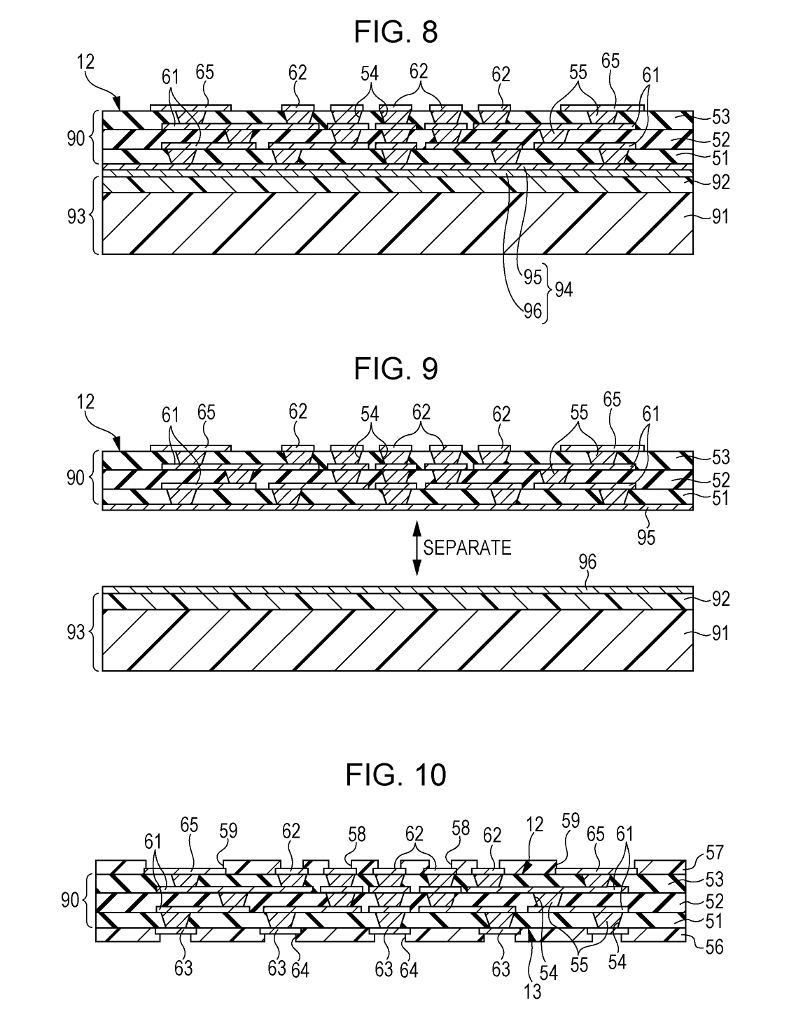

After that, a sheet-shaped insulating resin base material is stacked on the multilayer metal sheet 94, and is heated and pressurized under vacuum by using a vacuum heat press (not shown), so that the insulating resin base material is cured. Thus, the first resin insulating layer 51 is formed (see FIG. 6). Then, the via holes 54 are formed in the resin insulating layer 51 at predetermined positions by laser processing, and a desmearing process is performed to remove a smear in the via holes 54. Then, electroless copper plating and electro copper plating are performed by a known method to form the via conductors 55 in the via holes 54. Then, a conductor layer 61 is formed on the resin insulating layer 51 in a certain pattern by performing etching in accordance with a known method (for example, semi-additive method) (see FIG. 7). Then, by applying a method similar to the method for forming the first resin insulating layer 51 and the conductor layer 61, the second and third resin insulating layers 52 and 53 and another conductor layer 61 are formed on the first resin insulating layer 51. By performing the above-described manufacturing steps, a multilayer unit 90, in which the multilayer metal sheet 94, the resin insulating layers 51 to 53, and the conductor layers 61 are stacked on the support substrate 91, is formed (see FIG. 8).

Next, the resin insulating layer 53, which is the topmost layer, is subjected to plating so that the principal-surface-side electrodes 62 and 65 are formed on the principal surface 12 (see FIG. 8). In the present embodiment, the principal-surface-side electrodes 62 and 65 are formed on the resin insulating layer 53 in a certain pattern by a semi-additive method. More specifically, first, the via holes 54 are formed in the resin insulating layer 53 at predetermined positions by laser processing. Then, a desmearing process is performed to remove a smear in the via holes 54. Next, the surface of the resin insulating layer 53 is subjected to electroless copper plating, and then a dry film is provided on the resin insulating layer 53 to form a plating resist layer (not shown). Next, the plating resist layer is subjected to laser processing performed by a laser processing machine. Thus, openings having an inner diameter greater than the outer diameter of the via holes 54 at the top ends are formed at positions where the openings communicate with the via holes 54 in the resin insulating layer 53. Then, electro copper plating is performed so that the via conductors 55 are formed in the via holes 54, and the principal-surface-side electrodes 62 and 65, which are made mainly of copper, are formed on portions of the top surface of the resin insulating layer 53 (principal surface 12) that are exposed at the openings and on the top surfaces of the via conductors 55 that are also exposed at the openings. Then, the plating resist layer is removed, and an unnecessary electroless plating layer is also removed.

Next, the base material 93 is removed so that the copper film 95 is exposed. More specifically, the two copper films 95 and 96 included in the multilayer metal sheet 94 are separated from each other at the interface therebetween, so that the multilayer unit 90 is separated from the support substrate (see FIG. 9). Then, the copper film 95 on the back surface 13 (bottom surface) is etched into a certain pattern, so that the back-surface-side electrodes 63 are formed on the back surface 13 of the resin insulating layer 51 (see FIG. 10). After that, a photosensitive epoxy resin is applied to the resin insulating layer 51 on which the back-surface-side electrodes 63 are formed, and is cured so that the solder resist layer 56 is formed so as to cover the back surface 13 (see FIG. 10). Next, exposure and development processes are performed in a state in which a predetermined mask is placed on the solder resist layer 56, so that the openings 64 are formed in the solder resist layer 56 in a certain pattern.

A photosensitive epoxy resin is also applied to the resin insulating layer 53 on which the principal-surface-side electrodes 62 are formed, and is cured so that the solder resist layer 57 is formed so as to cover the principal surface 12 (see FIG. 10). Next, exposure and development processes are performed in a state in which a predetermined mask is placed on the solder resist layer 57, so that the openings 58 and 59 are formed in the solder resist layer 57 in a certain pattern (see FIG. 10).

Next, a metal mask (not shown) is placed on the principal surface 12 (more specifically, on the surface of the solder resist layer 57). The metal mask placed on the principal surface 12 is subjected to a hole-forming process performed by using a drill in advance. Accordingly, the mask has a plurality of openings at positions where the openings communicate with the openings 58 in the solder resist layer 57, and the principal-surface-side electrodes 62 are exposed at the openings in the mask.

Next, solder is supplied to the openings in the metal mask by printing. More specifically, a solder paste is applied to the principal-surface-side electrodes 62, which are exposed at the openings, by printing. Next, the multilayer unit 90 to which the solder paste has been applied by printing is placed in a reflow oven, and heated to a temperature higher than the melting point of the solder by 10° C. to 40° C. At this time, the solder paste is melted, and the solder bumps 70, which have a hemispherical shape, are formed in the openings. Then, the metal mask is removed. Thus, the intermediate product of the first substrate 11 is completed. The intermediate product of the first substrate 11 is divided into pieces by a known cutting apparatus or the like. As a result, the product units are separated from each other, and multiple products, each of which is the first substrate 11, are simultaneously produced.

After that, the IC chip 71 is mounted on the first substrate 11 in the IC-chip receiving region 73. At this time, the connection terminals 72 provided on the bottom surface of the IC chip 71 are placed on the solder bumps 70 arranged on the first substrate 11. Then, the temperature is increased to about 230° C. to 260° C., so that the solder bumps 70 are melted (reflow). Thus, the principal-surface-side electrodes 62 are connected to the connection terminals 72 by flip chip connection, and the IC chip 71 is mounted on the first substrate 11. Then, the gap between the principal surface 12 of the first substrate 11 and the IC chip 71 is filled with the underfill 74, and a curing process is performed. Thus, the gap is sealed with resin.

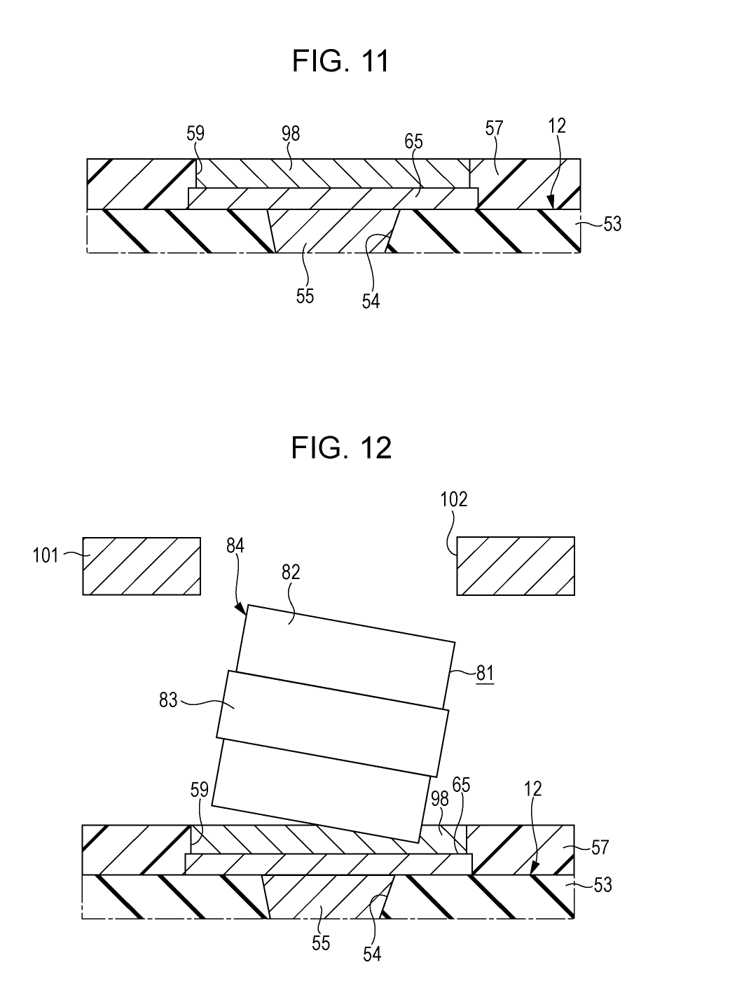

Next, a solder-paste supplying step is performed. More specifically, first, a metal mask (not shown) is placed on the principal surface 12 (more specifically, on the surface of the solder resist layer 57). The metal mask placed on the principal surface 12 is subjected to a hole-forming process performed by using a drill in advance. Accordingly, the mask has a plurality of openings at positions where the openings communicate with the openings 59 in the solder resist layer 57, and the principal-surface-side electrodes 65 are exposed at the openings in the mask. Next, solder paste 98 is supplied to the principal-surface-side electrodes 65 that are exposed at the openings in the metal mask and the openings 59 in the solder resist layer 57 (see FIG. 11). In the solder-paste supplying step according to the present embodiment, the solder paste 98 is supplied by printing. Then, the metal mask is removed.

Next, in a pillar-shaped-terminal arranging step, the pillar-shaped terminals 81 are arranged on the respective principal-surface-side electrodes 65 to which the solder paste 98 has been applied. More specifically, first, a positioning jig 101 used to position the pillar-shaped terminals 81 is prepared (see FIG. 12). Next, the pillar-shaped terminals 81 are inserted into respective pillar-shaped-terminal receiving holes 102 formed in the positioning jig 101 so that the pillar-shaped terminals 81 are arranged above the solder paste 98. In the present embodiment, each pillar-shaped-terminal receiving hole 102 has a uniform cross sectional shape, and the diameter thereof is set so that the pillar-shaped-terminal receiving hole 102 is capable of receiving the entire body of the corresponding pillar-shaped terminal 81 irrespective of the orientation of the pillar-shaped terminal 81. The positioning jig 101 is preferably made of a metal material having a high mechanical strength. For example, the positioning jig 101 may be made of an alloy of tungsten (W), carbon (C), and cobalt (Co).

Next, in a reflow step, the solder paste 98 is heated and melted. As a result, a portion of each pillar-shaped terminal 81 is immersed in the solder paste 98, and the pillar-shaped terminal 81 stands upright. More specifically, in the state in which the pillar-shaped terminal 81 is in contact with the solder paste 98, the temperature is increased to a temperature higher than the melting point of the solder by 10° C. to 40° C., so that the solder paste 98 is heated and melted (reflow). At this time, the bottom end of the pillar-shaped terminal 81 is immersed in the solder paste 98 (see FIG. 12). Accordingly, the pillar-shaped terminal 81 is influenced by the surface tension of the solder in the liquid phase, and changes its orientation so as to balance its weight. As a result, the pillar-shaped terminal 81 stands upright by itself. Since the solder blocking layer 83 exerts a solder-repelling force, the solder paste 98 in the liquid phase is repelled by the solder blocking layer 83 and accumulates in a region near the principal-surface-side electrode 65. This further makes it easier for the pillar-shaped terminal 81 to stand upright. As a result, multiple pillar-shaped terminals 81 are simultaneously soldered to the respective principal-surface-side electrodes 65 (see FIG. 2).

An intermediate product of the second substrate 21 is produced by a method similar to that for producing the intermediate product of the first substrate 11. The intermediate product of the second substrate 21 is structured such that a plurality of product units, each of which serves as the second substrate 21, are arranged along a plane. The intermediate product of the second substrate 21 is produced by the following method. That is, first, a base material similar to the base material 93 (see FIG. 6) is prepared. Then, a multilayer metal sheet similar to the multilayer metal sheet 94 (see FIG. 6) is provided on one surface of the base material.

After that, a sheet-shaped insulating resin base material is stacked on the multilayer metal sheet, and is heated and pressurized under vacuum by using a vacuum heat press (not shown), so that the insulating resin base material is cured. Thus, the first resin insulating layer 31 is formed. Then, the via holes 33 are formed in the resin insulating layer 31 at predetermined positions by laser processing, and a desmearing process is performed to remove a smear in the via holes 33. Then, electroless copper plating and electro copper plating are performed by a known method to form the via conductors 34 in the via holes 33. Then, the conductor layer 41 is formed on the resin insulating layer 31 in a certain pattern by performing etching in accordance with a known method (for example, semi-additive method). Then, the second resin insulating layer 32 is formed on the first resin insulating layer 31 by a method similar to the above-described method for forming the first resin insulating layer 31. By performing the above-described manufacturing steps, a multilayer unit, in which the multilayer metal sheet, the resin insulating layers 31 and 32, and the conductor layer 41 are stacked on the base material, is formed.

Next, the resin insulating layer 32, which is the topmost layer, is subjected to plating so that the principal-surface-side electrodes 42 are formed on the principal surface 22. In the present embodiment, the principal-surface-side electrodes 42 are formed on the resin insulating layer 32 in a certain pattern by a semi-additive method.

Next, two copper films included in the multilayer metal sheet are separated from each other at the interface therebetween, so that the multilayer unit is separated from the base material. Then, the copper film on the back surface 23 (bottom surface) is etched into a certain pattern, so that the back-surface-side electrodes 43 are formed on the back surface 23 of the resin insulating layer 31.

After that, a photosensitive epoxy resin is applied to the resin insulating layer 32 on which the principal-surface-side electrodes 42 are formed, and is cured so that the solder resist layer 35 is formed so as to cover the principal surface 22. Next, exposure and development processes are performed in a state in which a predetermined mask is placed on the solder resist layer 35, so that the openings 36 are formed in the solder resist layer 35 in a certain pattern. A photosensitive epoxy resin is also applied to the resin insulating layer 31 on which the back-surface-side electrodes 43 are formed, and is cured so that the solder resist layer 37 is formed so as to cover the back surface 23. Next, exposure and development processes are performed in a state in which a predetermined mask is placed on the solder resist layer 37, so that the openings 38 are formed in the solder resist layer 37 in a certain pattern.

Next, a metal mask (not shown) is placed on the back surface 23 (more specifically, on the surface of the solder resist layer 37). The metal mask placed on the back surface 23 is subjected to a hole-forming process performed by using a drill in advance. Accordingly, the mask has a plurality of openings at positions where the openings communicate with the openings 38 in the solder resist layer 37, and the back-surface-side electrodes 43 are exposed at the openings in the mask. Next, the solder portions 39 are formed by supplying solder paste to the back-surface-side electrodes 43, which are exposed at the openings in the metal mask and the openings 38 in the solder resist layer 37, by printing. Then, the metal mask is removed. Thus, the intermediate product of the second substrate 21 is completed. The intermediate product of the second substrate 21 is divided into pieces by a known cutting apparatus or the like. As a result, the product units are separated from each other, and multiple products, each of which is the second substrate 21, are simultaneously produced.

Next, the second substrate 21 is connected to the first substrate 11. More specifically, the top ends of the pillar-shaped terminals 81, which are arranged on the principal-surface-12 side of the first substrate 11, are brought into contact with the solder portions 39 arranged on the back-surface-23 side of the second substrate 21. In this state, the solder portions 39 are heated to a temperature higher than the melting point of the solder by 10° C. to 40° C., so that the solder portions 39 are heated and melted (reflow). Accordingly, the top ends of the pillar-shaped terminals 81 are immersed in the solder portions 39. As a result, the pillar-shaped terminals 81 are simultaneously soldered to the respective back-surface-side electrodes 43, and the second substrate 21 is connected to the first substrate 11. The circuit board 10 is manufactured by the above-described process.

The following advantages can be obtained by the present embodiment.

(1) In the circuit board 10 according to the present embodiment, the central region of each pillar-shaped terminal 81 (pillar-shaped terminal body 82) in the height direction is covered with the solder blocking layer 83. Therefore, in the process of bonding the pillar-shaped terminal 81 to the corresponding principal-surface-side electrode 65, when the bottom end of the pillar-shaped terminal 81 is immersed in the corresponding solder portion 80 (solder paste 98) that is heated and melted, the pillar-shaped terminal 81 is influenced by the surface tension or the like of the solder in the liquid phase and changes its orientation so as to balance its weight. As a result, the pillar-shaped terminal 81 stands upright by itself. Since the solder blocking layer 83 is made of the material 87 having a solder wettability lower than that of the pillar-shaped terminal body 82, the solder blocking layer 83 repels the solder portion 80 (solder paste 98) in the liquid phase so that the solder portion 80 (solder paste 98) accumulates in a region near the principal-surface-side electrode 65. This further makes it easier for the pillar-shaped terminal 81 to stand upright. Accordingly, even when the pitch between the adjacent terminals is reduced with a reduction in the size of the circuit board 10, since the pillar-shaped terminals 81 that easily stand upright are used as the terminals, a circuit board 10 in which the first substrate 11 can be easily connected to the second substrate 21 with the pillar-shaped terminals 81 provided therebetween can be provided.

(2) In the present embodiment, the bottom end surface 86 of the pillar-shaped terminal body 82 of each pillar-shaped terminal 81 is separated from the surface of the corresponding principal-surface-side electrode 65 on the first substrate 11. Therefore, the space between the bottom end surface 86 of the pillar-shaped terminal body 82 and the surface of the principal-surface-side electrode 65 can be reliably filled with the corresponding solder portion 80. As a result, the contact area between the pillar-shaped terminal body 82 and the solder portion 80 and the contact area between the principal-surface-side electrode 65 and the solder portion 80 are increased, so that the bonding strength between the principal-surface-side electrode 65 and the pillar-shaped terminal 81 can be increased. In addition, in the present embodiment, the top end surface 85 of the pillar-shaped terminal body 82 is separated from the surface of the corresponding back-surface-side electrode 43 on the second substrate 21. Therefore, the space between the top end surface 85 of the pillar-shaped terminal body 82 and the surface of the back-surface-side electrode 43 can be reliably filled with the corresponding solder portion 39. As a result, the contact area between the pillar-shaped terminal body 82 and the solder portion 39 and the contact area between the back-surface-side electrode 43 and the solder portion 39 are increased, so that the bonding strength between the back-surface-side electrode 43 and the pillar-shaped terminal 81 can be increased. Thus, the connection strength between the first substrate 11 and the second substrate 21 can be increased, and the reliability of the circuit board 10 can be increased accordingly.

The present embodiment may be modified as follows.

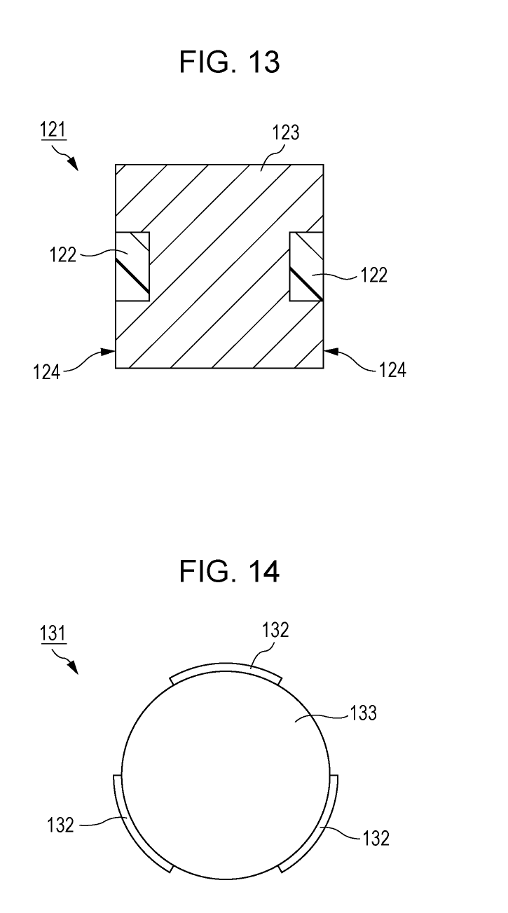

That is, in each pillar-shaped terminal 81 according to the above-described embodiment, the solder blocking layer 83 projects from the outer peripheral surface 84 of the pillar-shaped terminal body 82. However, as illustrated in FIG. 13, a pillar-shaped terminal 121 may include a solder blocking layer 122 that does not project from an outer peripheral surface 124 of a pillar-shaped terminal body 123 and is embedded in the pillar-shaped terminal body 123.

In addition, in each pillar-shaped terminal 81 according to the above-described embodiment, the solder blocking layer 83 extends over the entire perimeter of the outer peripheral surface 84 of the pillar-shaped terminal body 82. However, it is not necessary that the solder blocking layer extend over the entire perimeter of the outer peripheral surface of the pillar-shaped terminal body. For example, as illustrated in FIG. 14, a pillar-shaped terminal 131 may include a plurality of solder blocking layers 132 that are arranged with constant intervals therebetween in the circumferential direction of a pillar-shaped terminal body 133.

Although the bottom end surface 86 of the pillar-shaped terminal body 82 of each pillar-shaped terminal 81 and the surface of the corresponding principal-surface-side electrode 65 on the first substrate 11 are separated from each other in the above-described embodiment, they may instead be in contact with each other. Similarly, although the top end surface 85 of the pillar-shaped terminal body 82 and the surface of the corresponding back-surface-side electrode 43 on the second substrate 21 are separated from each other in the above-described embodiment, they may instead be in contact with each other.

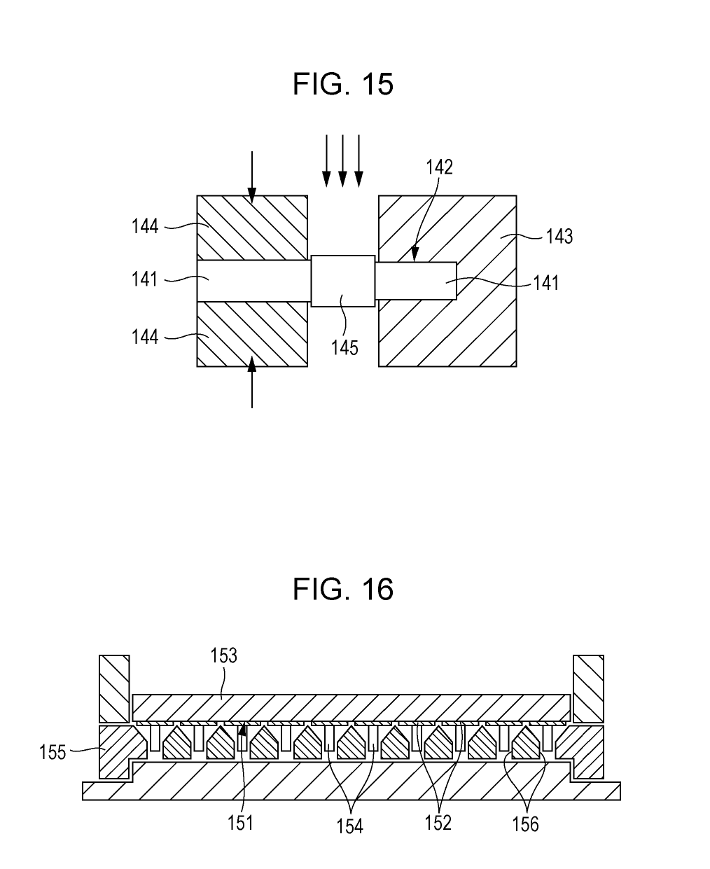

Each pillar-shaped terminal 81 may be formed by a method different from that in the above-described embodiment. For example, first, a pillar-shaped-terminal-body preparation step is performed to prepare a pillar-shaped terminal body 141 (see FIG. 15) made of a conductive material (for example, copper). Next, in a solder-blocking-layer forming step, an outer peripheral surface 142 of the pillar-shaped terminal body 141 is covered with a material (for example, an epoxy resin) having a solder wettability lower than that of the pillar-shaped terminal body 141. More specifically, first, a first end portion (right end portion in FIG. 15) of the pillar-shaped terminal body 141 is attached to a first chuck 143, and a second end portion (left end portion in FIG. 15) of the pillar-shaped terminal body 141 is attached to a second chuck 144. In this state, the material is blown toward the outer peripheral surface 142 of the pillar-shaped terminal body 141 in the space between the first chuck 143 and the second chuck 144. As a result, the material with which the outer peripheral surface 142 is covered serves as a solder blocking layer 145 that covers a central region of the outer peripheral surface 142 of the pillar-shaped terminal body 141 in the height direction. Then, unnecessary portions at both ends of the pillar-shaped terminal body 141 are cut. Thus, the pillar-shaped terminal 81 is completed.

The circuit board 10 according to the above-described embodiment includes the first substrate 11 and the second substrate 21. However, the present invention may be applied to a circuit board including only the first substrate 11.

The circuit board 10 according to the above-described embodiment has a POP structure in which two semiconductor packages (the first substrate 11 and the second substrate 21) are stacked together. However, the present invention may be applied to a circuit board having another structure. For example, the present invention may be applied to a circuit board having a structure in which a semiconductor package (first substrate) and an IC chip (second substrate) are stacked together.

Technical ideas of the above-described embodiment will now be described.

(1) The circuit board according to the above-described means 1 or 2, wherein a solder resist layer having openings are provided on the principal surface, the openings having an inner diameter greater than a maximum diameter of the pillar-shaped terminals.

(2) The circuit board according to technical idea (1), wherein the height of the pillar-shaped terminal body is smaller than the inner diameter of the openings in the solder resist layer.

(3) The circuit board according to the above-described means 1 or 2, wherein the maximum diameter of the pillar-shaped terminals is set so as to be smaller than the maximum diameter of the electrodes.

(4) The circuit board according to the above-described means 1 or 2, wherein the ratio of the height of the pillar-shaped terminal body to the outer diameter of the pillar-shaped terminal body is in the range of 1:1 to 3:1.

(5) The circuit board according to the above-described means 1 or 2, wherein the solder blocking layer projects from the outer peripheral surface of the pillar-shaped terminal body, and wherein each solder portion projects from the corresponding electrode, and the top end of the solder portion extends to the solder blocking layer.

(6) The circuit board according to the above-described means 1 or 2, wherein the pillar-shaped terminal body is made of copper.

(7) The circuit board according to the above-described means 1 or 2, wherein the principal surface is covered with a solder resist layer and the solder blocking layer is made of the same material as a resin material of the solder resist layer.

(8) The method for manufacturing the circuit board according to the above-described means 3, wherein, in the solder-paste supplying step, the solder paste is supplied by a printing method.

(9) The method for manufacturing the circuit board according to the above-described means 3, wherein, in the pillar-shaped-terminal arranging step, the pillar-shaped terminals are arranged above the respective electrodes by inserting the pillar-shaped terminals into respective pillar-shaped-terminal receiving holes formed in a positioning jig.

(10) A method for manufacturing a pillar-shaped terminal for a circuit board including a first substrate that is or is to be connected to a second substrate, the method including a pillar-shaped-terminal-body preparation step of preparing a pillar-shaped terminal body made of a conductive material; a material applying step of applying a material to the entire outer peripheral surface of the pillar-shaped terminal body, the material having a solder wettability lower than that of the pillar-shaped terminal body; and a solder-blocking-layer forming step of removing portions of the material that cover end portions of the pillar-shaped terminal body so that the remaining portion of the material serves as a solder blocking layer that covers a central region of the outer peripheral surface of the pillar-shaped terminal body in a height direction.

(11) A method for manufacturing a pillar-shaped terminal for a circuit board including a first substrate that is or is to be connected to a second substrate, the method including a pillar-shaped-terminal-body preparation step of preparing a pillar-shaped terminal body made of a conductive material; and a solder-blocking-layer forming step of applying a material to an outer peripheral surface of the pillar-shaped terminal body, the material having a solder wettability lower than that of the pillar-shaped terminal body, so that the applied material serves as a solder blocking layer that covers a central region of the outer peripheral surface of the pillar-shaped terminal body in a height direction.

What is claimed is:

1. A circuit board comprising:
a first substrate for connecting to a second substrate, the first substrate including a principal surface and a plurality of electrodes arranged on the principal surface; and
a plurality of pillar-shaped terminals bonded to respective electrodes with solder portions provided therebetween, the pillar-shaped terminals for connecting the first substrate to the second substrate,
wherein each pillar-shaped terminal includes a pillar-shaped terminal body made of a conductive material and a solder blocking layer that is made of a material having a solder wettability lower than a solder wettability of the pillar-shaped terminal body and that covers a central region of an outer peripheral surface of the pillar-shaped terminal body in a height direction.

2. The circuit board according to claim 1,
wherein each pillar-shaped terminal has a shape that is vertically symmetrical about the solder blocking layer, and
wherein an area of a region of the outer peripheral surface of the pillar-shaped terminal body that is not covered with the solder blocking layer is larger than an area of the region of the outer peripheral surface that is covered with the solder blocking layer.

3. The circuit board according to claim 1, wherein the solder blocking layer projects from the outer peripheral surface of the pillar-shaped terminal body.

4. The circuit board according to claim 1, wherein the solder blocking layer extends along an entire perimeter of the outer peripheral surface of the pillar-shaped terminal body in the central region of the pillar-shaped terminal body in the height direction.

5. A method for manufacturing the circuit board according to claim 1, the method comprising:
a substrate preparation step of preparing the first substrate having the electrodes arranged on the principal surface thereof;
a solder-paste supplying step of supplying a solder paste to the electrodes;
a pillar-shaped-terminal arranging step of arranging the pillar-shaped terminals on the respective electrodes to which the solder paste has been supplied; and
a reflow step of heating and melting the solder paste so that at least portions of the pillar-shaped terminals are immersed in the solder paste and the pillar-shaped terminals stand upright.

6. The method according to claim 5, wherein the principal surface is covered with a solder resist layer and the electrodes are exposed at openings that extend through the solder resist layer in a thickness direction, and
wherein, in the solder-paste supplying step, the solder paste is supplied to the openings.

7. A pillar-shaped terminal for a circuit board including a first substrate for connecting to a second substrate, the pillar-shaped terminal comprising:
a pillar-shaped terminal body made of a conductive material and including an outer peripheral surface having a central region in a height direction; and
a solder blocking layer made of a material having a solder wettability lower than a solder wettability of the pillar-shaped terminal body and covering the central region of the outer peripheral surface of the pillar-shaped terminal body.

8. The pillar-shaped terminal according to claim 7,
wherein the pillar-shaped terminal has a shape that is vertically symmetrical about the solder blocking layer, and
wherein an area of a region of the outer peripheral surface of the pillar-shaped terminal body that is not covered with the solder blocking layer is larger than an area of the region of the outer peripheral surface that is covered with the solder blocking layer.

9. The pillar-shaped terminal according to claim 7, wherein the solder blocking layer projects from the outer peripheral surface of the pillar-shaped terminal body.

10. The pillar-shaped terminal according to claim 7, wherein the solder blocking layer extends along an entire perimeter of the outer peripheral surface of the pillar-shaped terminal body.
